(19) United States
(12) Patent Application Publication
(10) Pub. No.: US 2026/0095160 A1
(43) Pub. Date: Apr. 2, 2026

(54) Low-Area Flip-Flop

(71) Applicant: TEXAS INSTRUMENTS INCORPORATED, Dallas, TX (US)

(72) Inventors: Arnab Khawas, Bangalore (IN); Gokul Sabada, Bangalore (IN); Badarish Subbannavar, Bangalore (IN)

(21) Appl. No.: 18/901,610

(22) Filed: Sep. 30, 2024

(51) Int. Cl. H03K 3/037; H03K 19/20

(52) U.S. Cl. CPC H03K 3/0372; H03K 19/20

(57) ABSTRACT

A flip-flop logic circuit may be designed to reduce a number of transistors, yet still maintain its functionality. One flip-flop may include an inverter and two transmission gates to implement an inverting multiplexer, which may be expected to reduce a number of transistors. Another flip-flop may include a transmission gate, another transmission gate, and a tri-state inverter to implement an inverting multiplexer, which may also reduce a number of transistors. Other substitutions may be made, such as using a transmission gate in place of an inverter in series with a tri-state inverter, which may also reduce a number of transistors.

### TECHNICAL FIELD

The present disclosure relates generally to an electronic system and, in particular embodiments, to a low-area flip-flop.

### BACKGROUND

Flip-flops may be used in a variety of different applications, such as clock dividers, memory elements, and the like.

### SUMMARY

In accordance to an embodiment, a circuit includes: a first inverter having an output; a first transmission gate having an input, an output, and an enable input, where the input of the first transmission gate is coupled to the output of the first inverter; a first latch having an input and an output, the input of the first latch coupled to the output of the first transmission gate; a second latch having an input and an output, the input of the second latch coupled to the output of the first latch; and a second transmission gate having an input and an output, the input of the second transmission gate coupled to the output of the second latch.

In accordance to an embodiment, a flip-flop circuit includes: a first input configured to receive a first data signal; a first latch coupled in series with the first input; a second latch coupled in series with the first latch; and a first transmission gate, coupled on a feedback path between the first latch and the second latch, where the first transmission gate includes a first enable input configured to receive a first enable signal.

In accordance to an embodiment, a multiplexer circuit includes: a first data input configured to receive a first data signal; a transmission gate coupled with the first data input, where the transmission gate includes a first data output, a first enable input configured to receive an enable signal, and a second enable input configured to receive a complementary enable signal; and a tri-state inverter including: a second data input configured to receive a second data signal, a third enable input configured to receive the enable signal, and a fourth enable input configured to receive the complementary enable signal; where a second data output of the tri-state inverter is coupled to the first data output.

In accordance to an embodiment, a flip-flop includes: a multiplexer having a first multiplexer input; a transmission gate having a first data input coupled with an output of the multiplexer, where the transmission gate includes a first data output, a first enable input configured to receive an enable signal, and a second enable input configured to receive a complementary enable signal; a tri-state inverter including: a second data input, a third enable input configured to receive the enable signal, and a fourth enable input configured to receive the complementary enable signal, where a second data output of the tri-state inverter is coupled to the first data output; a first latch having an input coupled to the second data output; and a second latch having an input coupled to an output of the first latch, where an output of the second latch is coupled to the first multiplexer input.

### BRIEF DESCRIPTION OF THE DRAWINGS

Having thus described the invention in general terms, reference will now be made to the accompanying drawings, wherein:

FIG. 1 is an illustration of an exemplary enable flip-flop.

FIG. 2 is an illustration of an exemplary scan enable flip-flop.

FIG. 3 is an illustration of an example enable flip-flop, according to some embodiments.

FIG. 4 is an illustration of an example enable flip-flop, according to some embodiments.

FIG. 5 is an illustration of example scan enable flip-flop, according to some embodiments.

FIG. 6 is an illustration of example scan enable flip-flop, according to some embodiments.

FIG. 7 is an illustration of example scan enable flip-flop at a transistor level, according to some embodiments.

FIG. 8 is an illustration of an example scan enable flip-flop at a transistor level, according to some embodiments.

FIGS. 9A-B is an illustration of a method of transformation of the scan enable flip-flop of FIG. 2 into an example scan enable flip-flop, according to some embodiments.

FIG. 10 is an illustration of a transistor-level example of the transformation from Step 3 to Step 4 of FIGS. 9A-B, according to some embodiments.

FIG. 11 is a transistor-level illustration of an implementation of the example scan enable flip-flop of FIGS. 9A-B, according to some embodiments.

FIG. 12 is an illustration of an example flip-flop, according to some embodiments.

FIG. 13 is an illustration of an example flip-flop, according to some embodiments.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

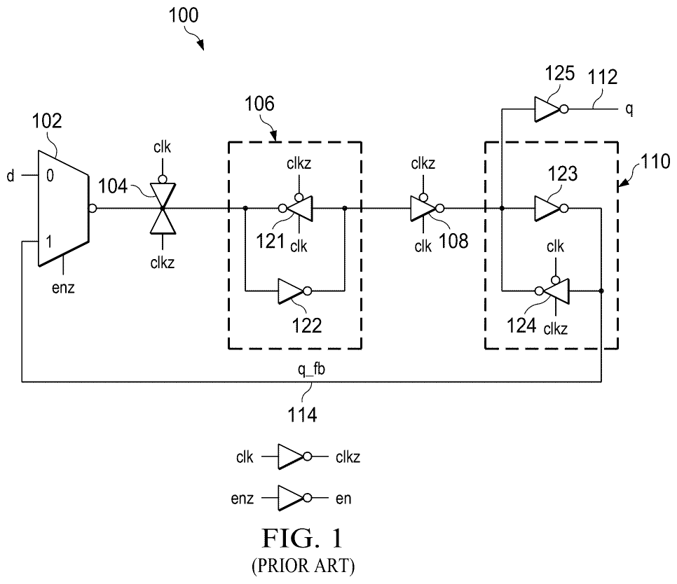

FIG. 1 is an illustration of exemplary enable flip-flop 100. The enable flip-flop 100 includes an inverting multiplexer 102 coupled with a clocking transmission gate 104. The clocking transmission gate 104 outputs to a first latch 106 (also called a master latch). The master latch 106 outputs to a clock-enabled tri-state inverter 108. The output of the clock-enabled tri-state inverter 108 is fed to an input of the second latch 110 (also called a slave latch). The output (q) of the slave latch 110 may be accessed at node 112, and it is also fed back to an input of the inverting multiplexer 102 on feedback path 114.

The inverting multiplexer 102 includes two inputs-(d) for data and q_fb (the fed-back output). The master latch 106 includes clock-enabled tri-state inverter 121, which is cross coupled with inverter 122. The slave latch 110 includes an inverter 123, which is cross coupled with a clock-enabled tri-state inverter 124. The node 112 is disposed at an output of inverter 125.

The inverting multiplexer 102 selects d if enz (the enable signal) is a digital 0. Otherwise, the inverting multiplexer 102 selects q_fb. The transmission gate 104 passes the output of the inverting multiplexer 102 to the input of the master latch 106 if the clock signal (clk) is a digital 0; if the clock signal is a digital 1, the transmission gate 104 blocks the signal from the inverting multiplexer 102.

The tri-state inverter 121 inverts its input (i.e., acts as a traditional inverter) when clk is a digital 1; otherwise, the tri-state inverter 121 causes its output to float (output at high impedance). With respect to tri-state inverter 124, tri-state inverter 124 acts as a regular inverter when clk is a digital 0; when clk is a digital 1, it's the output of tri-state inverter 124 floats (output at high impedance). Tri-state inverter 108 operates similarly to tri-state inverter 121.

In short, the enable flip-flop 100 stores and outputs the data d unless the enable signal enz is a digital 1, in which case the flip-flop 100 restores its previous output state. A truth table for an enable flip-flop, such as enable flip-flop 100, is given below at Table 1:

TABLE 1

| enz | d | q |
|---|---|---|
| 1 | X | q previous |
| 0 | 0 | 0 (with clock positive edge) |
| 0 | 1 | 1 (with clock positive edge) |

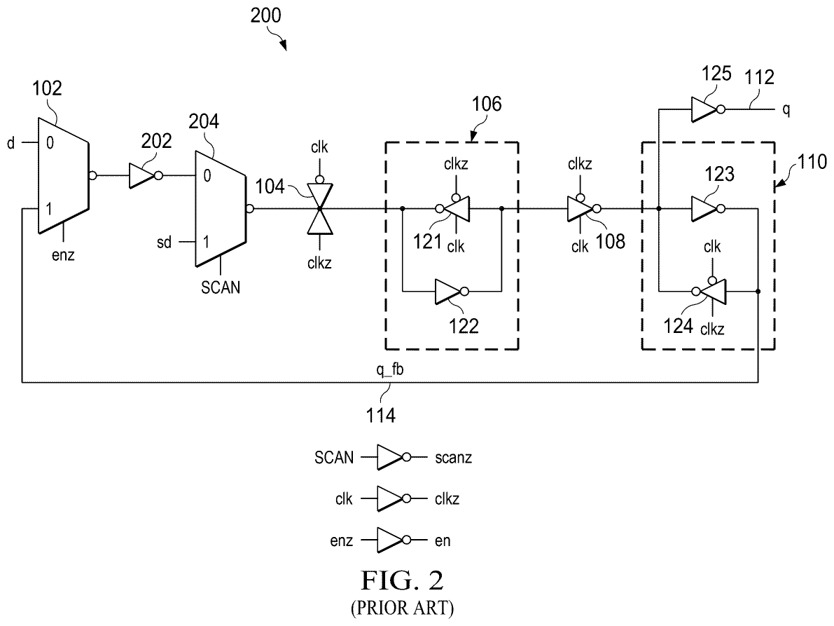

FIG. 2 is an illustration of exemplary scan enable flip-flop 200. Flip-flop 200 is similar to flip-flop 100, though flip-flop 200 adds inverter 202 at the output of inverting multiplexer 102 and adds inverting multiplexer 204. The inverting multiplexer 102 outputs a signal to the input of inverter 202, which outputs a signal to a first input of inverting multiplexer 204. The other input of inverting multiplexer 204 is configured to receive scan data (sd). The inverting multiplexer 204 is controlled by the scan enable signal (scan), so that either the data/feedback path or the scan data is selected based on the value of the scan enable signal. Specifically, when the value of the scan enable signal is a digital 0, an inverted version of the data/feedback is passed to the input of the master latch 106; when the value of the scan enable signal is equal to a digital 1, the inverting multiplexer 204 passes an inverted version of the scan data sd signal to the input of the master latch 106.

The scan circuitry (inverter 202 and inverting multiplexer 204) are coupled between the enable circuitry (inverting multiplexer 102) and an input of the master latch 106. This coupling of the inverting multiplexer 204 gives priority to the scan data because the scan data may be unaffected by the state of the enable signal enz.

Flip-flops, such as flip-flops 100 and 200, may be implemented as standard cells and used in various logic designs in relatively large quantities.

Savings of a few transistors (or even a single transistor) in a flip-flop (such as a flip-flop implemented as a standard cell) may advantageously result in noticeable savings of semiconductor area, e.g., when a given flip-flop design is used a relatively large number of times in an integrated circuit.

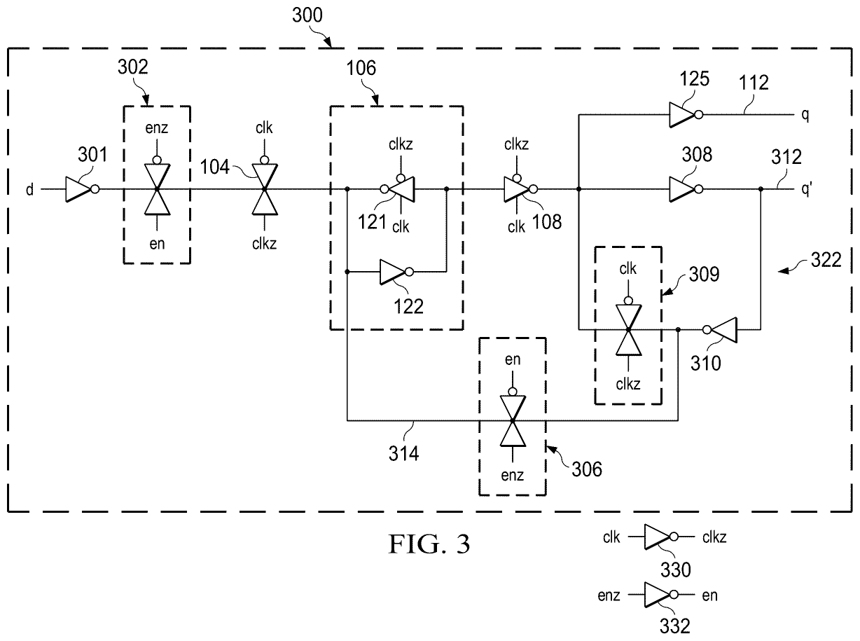

FIG. 3 is an illustration of enable flip-flop 300, according to some embodiments. FIG. 3 includes a data input at an input node of an inverter 301. The data signal is labeled d. The output of inverter 301 is coupled with an input of transmission gate 302. The output of transmission gate 302 is coupled to the input of transmission gate 104 so that is fed to master latch 106. The output of master latch 106 is fed to the input of a slave latch 322 via tri-state inverter 108.

The slave latch 322 includes cross coupled inverters 308 and 310 and transmission gate 309. The inverter 308 receives at its input the output from master latch 106. The inverter 310 has its input coupled to the output of inverter 308. The output of inverter 308 may be used as an output data signal q′. Similarly, the output of inverter 125 may be used as an output data signal q, where the input of inverter 125 is coupled to the input of inverter 308.

In some embodiments, the node 112 may be used as a data output of flip-flop 300, e.g., to avoid directly loading the slave latch. For example, in some embodiments, node 112 is the output of flip-flop 300 and may be connected to other circuits (not shown in FIG. 3).

The signals q and q′ may be similar or identical, though there may be some amount of (e.g., negligible) timing delay or gain difference between the two. In some embodiments, inverter 125 may be omitted and inverter 308 may be used for both driving the input of inverter 310 and as the output of flip-flop 300.

The output of inverter 310 is coupled with an input of transmission gate 309, and the output of the transmission gate 309 is coupled with the input of the inverter 308. There is an intermediate node between the output of inverter 310 and the input of transmission gate 309, and feedback path 314 couples to such intermediate node and also couples to the input of inverter 122. Transmission gate 306 is placed on the feedback path 314 between the intermediate node and the input of inverter 122.

The truth table of enable flip-flop 300 is the same as the truth table of Table 1. However, the physical components and arrangements of those components are different between FIG. 1 and FIG. 3. For instance, FIG. 3 uses different logic gates to implement functionality of inverting multiplexer 102. Inverter 301, transmission gate 302, and transmission gate 306 provide multiplexing for the data signal and feedback. When the enable signal enz is at a value of digital 0, the transmission gate 302 allows the output of inverter 301 to pass to the input of master latch 106. When the enable signal enz is at a value of digital 0, transmission gate 306 blocks the feedback path 314. In such an instance, the value of the data signal d gets saved and then output as the output signal q and q′.

When the enable signal enz is at a value of digital 1, transmission gate 302 isolates the output of inverter 301 from the input of master latch 106, and the transmission gate 306 electrically couples the intermediate node at the output of inverter 310 with the input of inverter 122 in the master latch 106. In such an instance, the currently saved state in the slave latch gets fed back to the master latch 106 via feedback path 314 and output as the output signal q and q′.

Although not shown herein, there may be a clock, such as a system clock, located either off chip or on-chip that provides the clock signal clk. A flip-flop (e.g., 300) may use the clock signal for synchronous operation.

Each of the transmission gates 302 and 306 may be implemented with two transistors, and the inverter 301 may be implemented with two transistors, to make a total of six transistors. By contrast, in FIG. 1, the inverting multiplexer 102 may be implemented with eight transistors. Therefore, the embodiment of FIG. 3 includes at least a two-transistor savings over the embodiment of FIG. 1.

In some embodiments, an integrated circuit (IC) includes a plurality of flip-flops 300, the IC generating signals clk and clkz (e.g., using inverter 330), and enz and en (e.g., using inverter 332), and providing such generated signals to all of the plurality of flip-flops 300. Thus, in some embodiments, inverters 330 and 332 are external to flip-flop 300, and only one inverter 330 and only one inverter 332 may be used for providing signals clkz and en to the plurality of flip-flops 300.

Although FIG. 3 illustrates the generation of signal clkz by inverting signal clk, in some embodiments, signal clk may be generated by inverting signal clkz. Although FIG. 3 illustrates the generation of signal en by inverting signal enz, in some embodiments, signal enz may be generated by inverting signal en.

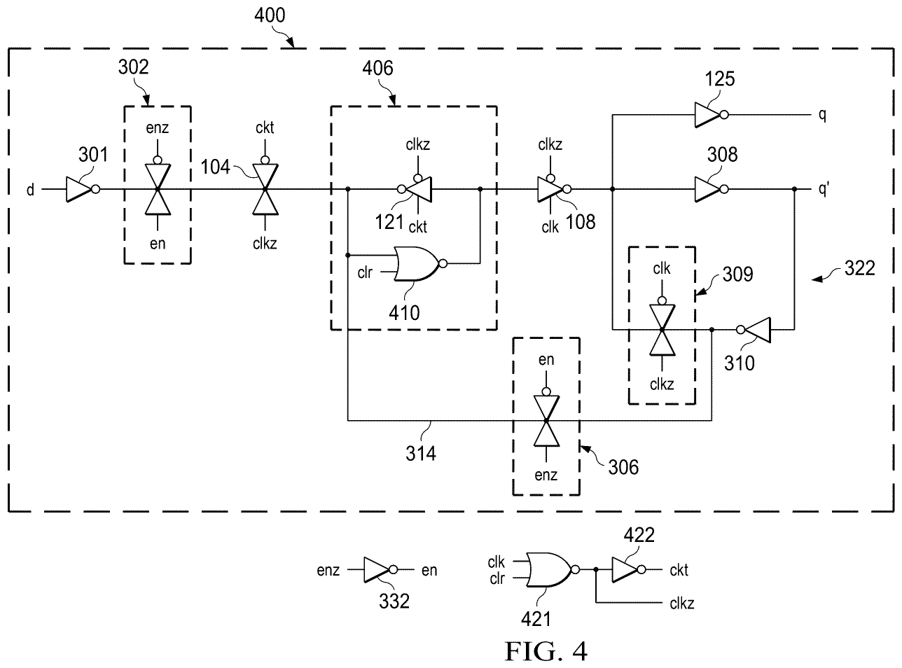

FIG. 4 is an illustration of enable flip-flop 400, according to some embodiments. Flip-flop 400 is similar to flip-flop 300, though flip-flop 400 includes master latch 406, which has a NOR gate 410 cross-coupled with the tri-state inverter 121. The NOR gate 410 has two inputs, one input receiving the output of tri-state inverter 121, and the other input receiving a clear (clr) signal. The output of NOR gate 410 is coupled to the input of tri-state inverter 121 and the input of tri-state inverter 108.

In the embodiment illustrated in FIG. 4, if the clr signal equals a digital 1, then the outputs q and q′ go to a digital 0. In other words, the NOR gate 410 provides an asynchronous clear function regardless of the state of the enable signal enz or the state of the data signal d. Other than that, the truth table of flip-flop 400 conforms to that shown in Table 1. In some implementations, the clock signal clk and the clear signal clr may be gated according to NOR gate 421 and inverter 422, thereby allowing the clr signal (as a digital 1) to cause a state change at q and q′ regardless of the value of the clock signal.

In some embodiments, an IC includes a plurality of flip-flops 400. In some embodiments, gates 421 and 422 are external to flip-flop 400, and only one NOR gate 421 and one inverter 422may be used for providing signals ckt and clkz to the plurality of flip-flops 400.

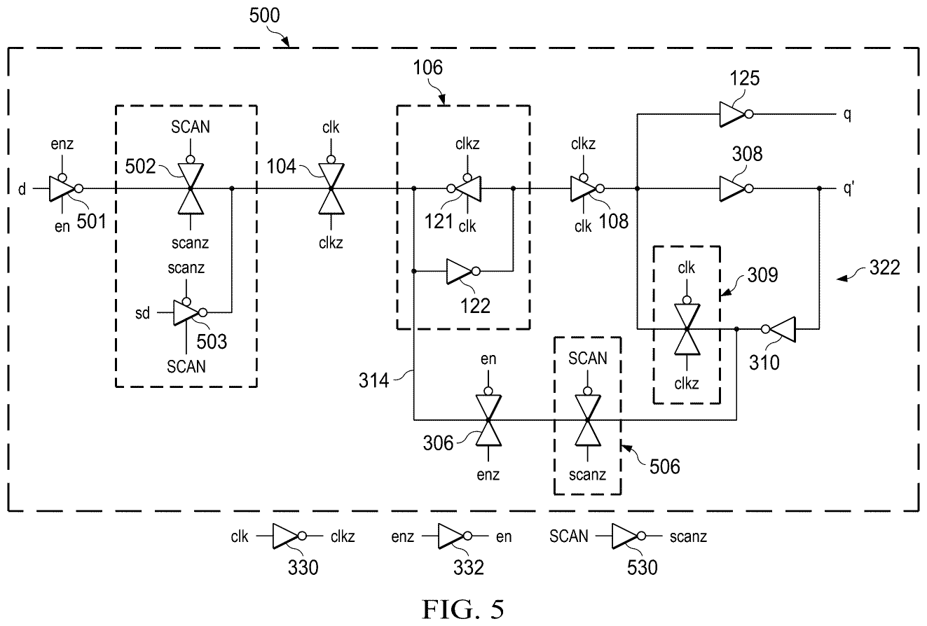

Although FIG. 4 illustrates the generation of signal clkz be inverting signal clk (using NOR gate 421), in some embodiments, signal clk may be generated by inverting signal clkz. FIG. 5 is an illustration of scan enable flip-flop 500, according to some embodiments. Scan enable flip-flop 500 provides the same scan data priority over the data/feedback path, as described above with respect to FIG. 2, though the physical components and arrangements of those components are different between FIGS. 2 and 5.

Scan enable flip-flop 500 implements inverter 301 and transmission gate 302 as tri-state inverter 501, which includes the functionality of both inverter 301 and transmission gate 302. When the enable signal enz is a digital 0, the tri-state inverter 501 outputs an inverted version of the data signal d. Otherwise, when the enable signal enz is a digital 1, the tri-state inverter 501 causes its output to float (output at high impedance). The tri-state inverter 501 with the transmission gate 306 provide the functionality of inverting multiplexer 102.

The output of tri-state inverter 501 is coupled with an input of transmission gate 502, and the output of transmission gate 502 is coupled to the input of master latch 106 via transmission gate 104. The feedback path 314 further includes transmission gate 506 disposed between the output of inverter 310 of the slave latch and the input of inverter 122 of the master latch 106. The output of tri-state inverter 503 is coupled between the output of transmission gate 502 and the input of transmission gate 104.

When the value of the scan enable signal (scan) is a digital 0, transmission gate 502 is ON and creates an electrical path from the output of the tri-state inverter 501 to the input of master latch 106. Similarly, when scan is a digital 0, the transmission gate 506 is ON and creates an electrical path between the output of inverter 310 and the input of transmission gate 306. Further, when the scan enable signal is digital 0, tri-state inverter 503 causes its output to float (output at high impedance). When the scan enable signal is a digital 0, the scan functionality does not pass the value of the second data signal (sd) to the output q or q′. Rather, when the scan enable signal is a digital 0, scan enable latch 500 outputs either the value of the data signal d or the previous value of q or q′.

Continuing with the example, when the value of the scan enable signal is a digital 1, transmission gate 502 is OFF, thereby isolating the output of tri-state inverter 501 from the input of master latch 106. The tri-state inverter 503 outputs the complement of the sd signal to the input of the transmission gate 104 and the input of master latch 106. Furthermore, the transmission gate 506 is OFF and isolates the master latch 106 from the slave latch on the feedback path 314.

Thus, regardless of the value of the enable signal enz, a scan enable signal of a value of 1 will result in passing the value of the scan data signal sd to the outputs q and q′. However, when the value of the scan enable signal is a 0, the scan enable flip-flop 500 outputs either the value of the data signal d or the previous value of q or q′, depending upon whether the enable signal enz is a 0 or a 1.

An advantage of flip-flop 500 over flip-flop 200 (FIG. 2) is that flip-flop 500 saves two transistors by implementing the functionality of inverting multiplexer 102 (FIG. 2) with items 501 and 306. Flip-flop 500 also saves two more transistors by implementing the functionality of inverting multiplexer 204 and inverter 202 with items 502, 503, and 506. As a result, flip-flop 500 saves at least four transistors over flip-flop 200.

In some embodiments, an IC includes a plurality of flip-flops 500. In some embodiments, inverter 530 is external to flip-flop 500, and only one inverter 530 may be used for providing signal scanz to the plurality of flip-flops 500.

Although FIG. 5 illustrates the generation of signal scanz by inverting signal SCAN, in some embodiments, signal SCAN may be generated by inverting signal scanz.

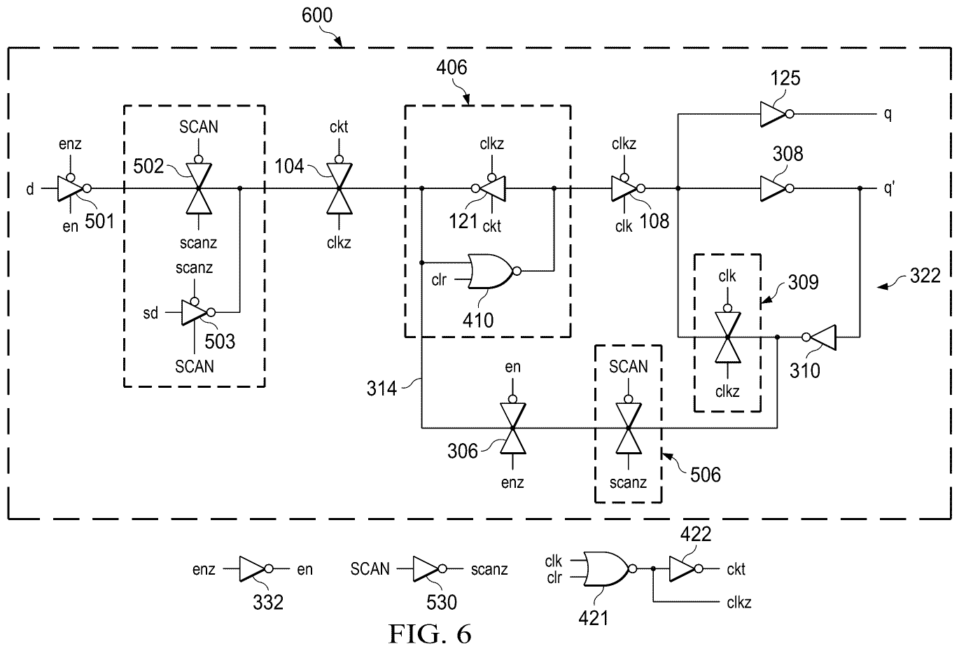

FIG. 6 is an illustration of example scan enable flip-flop 600, according to some embodiments. Flip-flop 600 is similar to flip-flop 500, but flip-flop 600 includes master latch 406 having NOR gate 410. As in FIG. 4, the NOR gate 410 includes an input that receives the output of the tri-state inverter 121 and another input that receives a clear signal clr. The output of the NOR gate 410 is coupled with the input of tri-state inverter 121 and the input of tri-state inverter 108.

Flip-flop 600 operates in a similar manner as flip-flop 500, except that a digital value of 1 for the clr signal will cause the outputs q and q′ to go to zero. This is true regardless of the value of the scan enable signal, the enable signal enz, the data signal d, or the scan data signal sd.

As noted above, the embodiment of FIG. 5 includes at least a four-transistor savings over the flip-flop of FIG. 2. The same transistor savings exists for FIG. 6 over a system similar to that of FIG. 2 but with a similar asynchronous clear functionality.

In some embodiments, an IC may include a plurality of flip-flops 300, 400, 500, and/or 600.

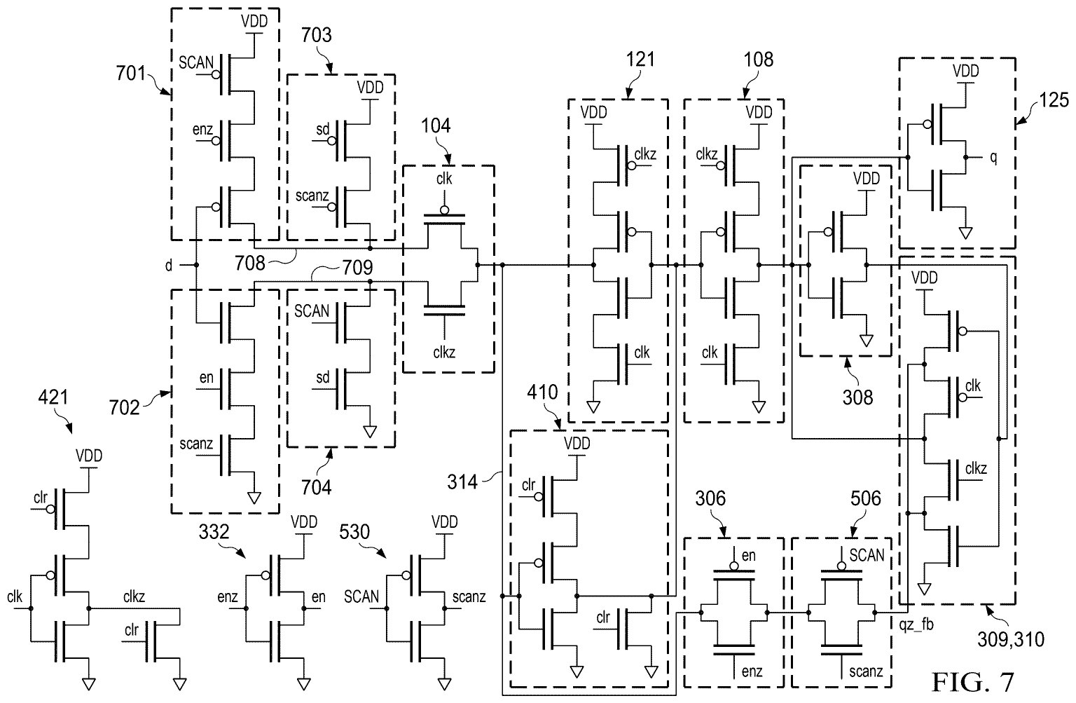

FIG. 7 is an illustration of example scan enable flip-flop 600 at a transistor level, according to some embodiments. In FIG. 7, the tri-state inverter 501, tri-state inverter 503, and transmission gate 502 are implemented as groups of transistors 701-704.

The first group of transistors 701 includes three P-type transistors arranged in series between VDD and node 708. Node 708 may be a source or a drain terminal of the P-type transistor of the transmission gate 104. The first group of transistors 701 are arranged to receive the data signal (d), the enable signal enz, and the scan enable signal at their control terminals.

The second group of transistors 702 includes three N-type transistors arranged in series between node 709 and ground. In this example, node 709 may be a source or drain terminal of the N-type transistor of the transmission gate 104. The transistors of the group of transistors 702 are configured to receive the data signal (d), the complement (en) of the enable signal enz, and the complement (scanz) of the scan enable signal at their control terminals.

The third group of transistors 703 includes two P-type transistors arranged in series between VDD and node 708. The transistors are configured to receive the scan data (sd) signal and the complement of the scan enable signal at their control terminals.

The fourth group of transistors 704 includes two N-type transistors arranged in series between node 709 and ground. The fourth group of transistors is configured to receive the scan enable signal (scan) and the scan data signal at their control terminals.

Furthermore, FIG. 7 illustrates an inverter 530 producing the complement (scanz) of the scan enable signal by receiving the scan enable signal at its input. Also, inverter 332 produces the complement (en) of the enable signal enz.

The transistor-level embodiment of FIG. 7 includes a total of 44 transistors. This is four transistors less than would be expected of a similar system that implements multiplexer functionality using two eight-transistor inverting multiplexers.

In the present disclosure, the transistors are illustrated as metal oxide semiconductor field-effect transistors (MOSFETs), though the scope of embodiments may include other types of transistors, such as bipolar junction transistors (BJTs), and the like.

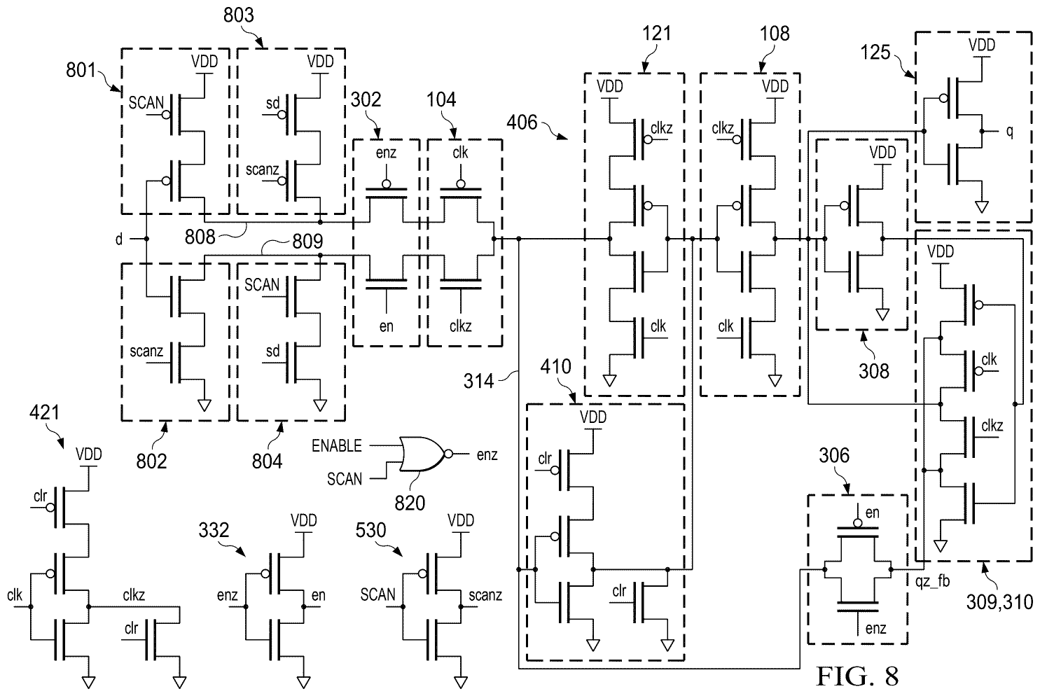

FIG. 8 is an illustration of an example scan enable flip-flop 800 at a transistor level, according to some embodiments. The logical behavior of scan enable flip-flop 800 is the same as for scan enable flip-flop 600 of FIGS. 6-7. However, FIG. 8 illustrates an architecture that may be used to save two more transistors versus the implementation of FIG. 7.

Scan enable flip-flop 800 includes four groups of transistors 801-804. The four groups of transistors are coupled to the transmission gate 302 and the transmission gate 104. The transmission gate 302 and the transmission gate 104 are connected in series to the input of the master latch 406, where the master latch 406 includes tri-state inverter 121 and NOR gate 410, such as in FIG. 4.

The groups of transistors 801 and 803 are coupled to the transmission gate 302 by node 808. Node 808 in this example may be a source or a drain of the P-type transistor of transmission gate 302. The groups of transistors 802 and 804 are coupled to the transmission gate 302 by node 809, which in this example may be a source or a drain of the N-type transistor of transmission gate 302.

The group of transistors 801 includes two P-type transistors coupled in series between VDD and node 808. The transistors of group 801 are configured to receive the scan enable signal (scan) and the data (d) signal at their control terminals.

The group of transistors 802 includes two N-type transistors coupled in series between node 809 and ground. The transistors of group 802 are configured to receive the data signal and the complement (scanz) of the scan enable signal at their control terminals.

The group of transistors 803 includes two P-type transistors coupled in series between VDD and node 808. The transistors of group 803 are configured to receive the scan data (sd) signal and the complement of the scan enable signal at their control terminals.

The group of transistors 804 includes two N-type transistors arranged in series between the node 809 and ground. The transistors of group 804 are configured to receive the scan enable signal and the scan data signal at their control terminals.

Of note in FIG. 8 is that transmission gate 506, which is controlled by the scan enable signal complement scanz, is not included. The total number of transistors is 42, for a savings of two transistors versus the implementation of FIG. 7. Nevertheless, the architecture of FIG. 8 is facilitated by gating the complement (en) of the enable signal and the scan enable signal, as illustrated by NOR gate 820, which is implemented outside of flip-flop 800. For instance, the input “enable” to NOR gate 820 may be an external signal coming from the system, and the output of NOR gate 820 may be sent as a primary enable enz pin (not shown) to the flip flop 800. While the NOR gate 820 may be expected to add transistors to the implementation of FIG. 8, in some implementations, the NOR gate 820 (or other appropriate gating) may be implemented in a separate subsystem or a separate chip, thereby allowing the subsystem or chip that includes scan enable flip-flop 800 to enjoy the two-transistor savings.

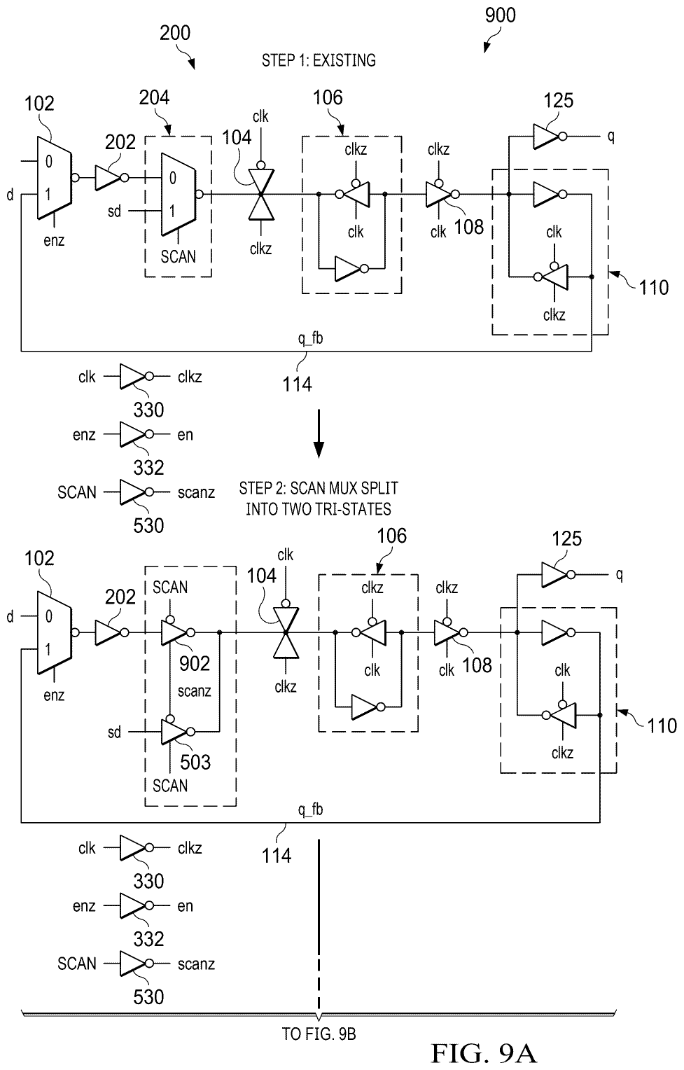

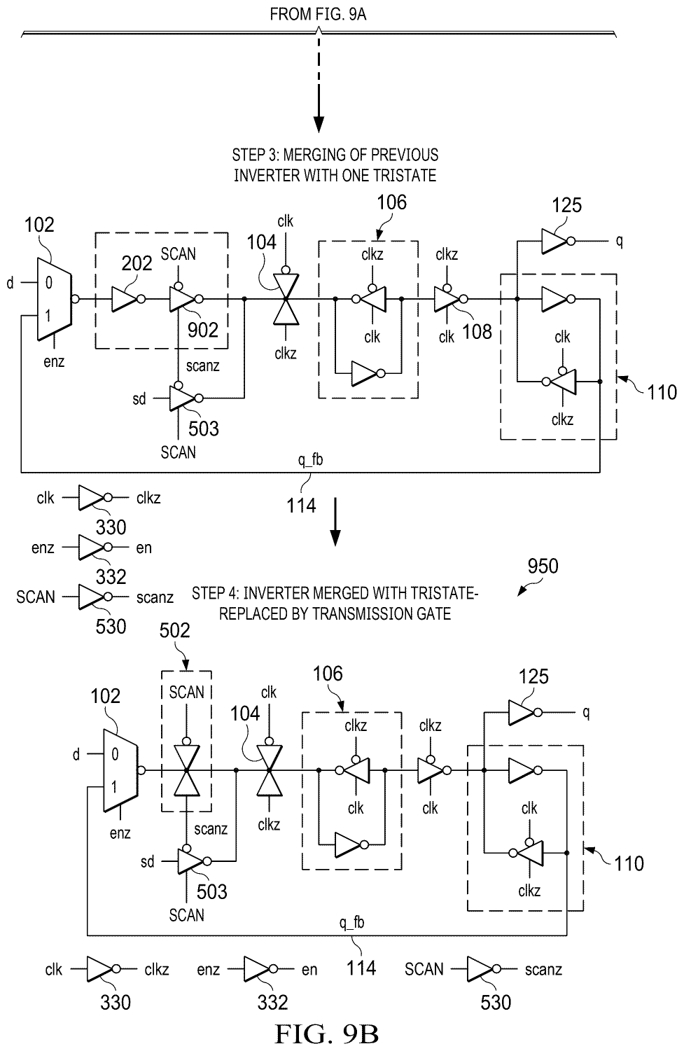

FIGS. 9A-B is an illustration of method 900 of transforming the scan enable flip-flop 200 of FIG. 2 into example scan enable flip-flop 950, according to some embodiments.

Step 1 shows flip-flop 200 of FIG. 2. At Step 2, the scan inverting multiplexer 204 is replaced with two tri-state inverters 902 and 503. Tri-state inverter 902 receives at its input the output from inverter 202. Inverter 202 receives as input the output of inverting multiplexer 102. The output of tri-state inverter 902 is coupled to transmission gate 104. Tri-state inverter 902 is controlled by the scan enable signal and the complement (scanz) of the scan enable signal. In this example, tri-state inverter 902 is ON when scan enable is a digital 0 and is OFF when scan enable is a digital 1.

The tri-state inverter 503 receives at its input the scan data (sd) signal, and its output is transmitted to the input of the transmission gate 104. The tri-state inverter 503 is controlled by the complement (scanz) of the scan enable signal so that tri-state inverter 503 is ON when scanz is a digital 0 and is OFF when scanz is a digital 1. Note that the ON and OFF states of tri-state inverter 503 are opposite of the ON and OFF states of tri-state inverter 902.

At Step 3, it is noted that inverter 202 and tri-state inverter 902 are in series between the inverting multiplexer 102 and the transmission gate 104. Step 4 illustrates that the inverter 202 and the tri-state inverter 902 may be combined by replacing both of those components with transmission gate 502. Transmission gate 502 receives at its input the output from inverting multiplexer 102. The output of transmission gate 502 is at a node that includes the output of tri-state inverter 503 and the input to transmission gate 104. Put another way, the output of transmission gate 502 is coupled with the input of master latch 106 via transmission gate 104.

Transmission gate 502 is ON when the scan enable signal is a digital 0, and transmission gate 502 is OFF when the scan enable signal is a digital 1. When transmission gate 502 is ON, it may pass the output from the inverting multiplexer 102 to the input of the master latch 106; when transmission gate 502 is OFF, it isolates the output of inverting multiplexer 102 from the input of master latch 106 and, instead, allows the output of tri-state inverter 503 to be applied to the input of the master latch 106.

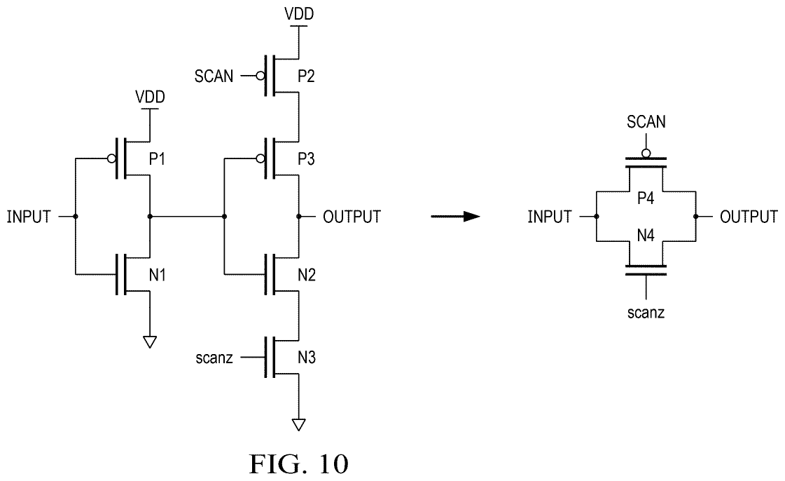

FIG. 10 is an illustration of a transistor-level example of the transformation from Step 3 to Step 4 of FIGS. 9A-B, according to some embodiments.

On the left, an inverter (e.g., inverter 202) is formed by transistor P1 and transistor N1 arranged between VDD and ground. The input node is coupled to the control terminals of P1 and N1. The output of the inverter is fed to an input of the tri-state inverter (e.g., tri-state inverter 902). The tri-state inverter includes transistors P3 and N2, coupled in series and both receiving the output of the inverter at their control terminals. P2 and P3 are arranged in series, and N2 and N3 are arranged in series. In this example, P2 receives the scan enable signal at its control terminal, and N3 receives the complement of the scan enable signal at its control terminal. The output node of the circuit is taken from the source/drain terminals of transistors P3 and N2.

The transformation includes reducing the circuit on the left to the transmission gate on the right. The transmission gate (e.g., transmission gate 502) includes two transistors, P4 and N4. The transistors P4 and N4 are arranged in parallel between the input node and the output node, so that a source/drain of transistor P4 is coupled to a source/drain of transistor N4 at the input node, and a drain/source of transistor P4 is coupled to a drain/source of transistor N4 at the output node. When the scan enable signal is a digital 0, both transistors P4 and N4 are ON, and when the scan enable signal is a digital 1, both transistors P4 and N4 are OFF.

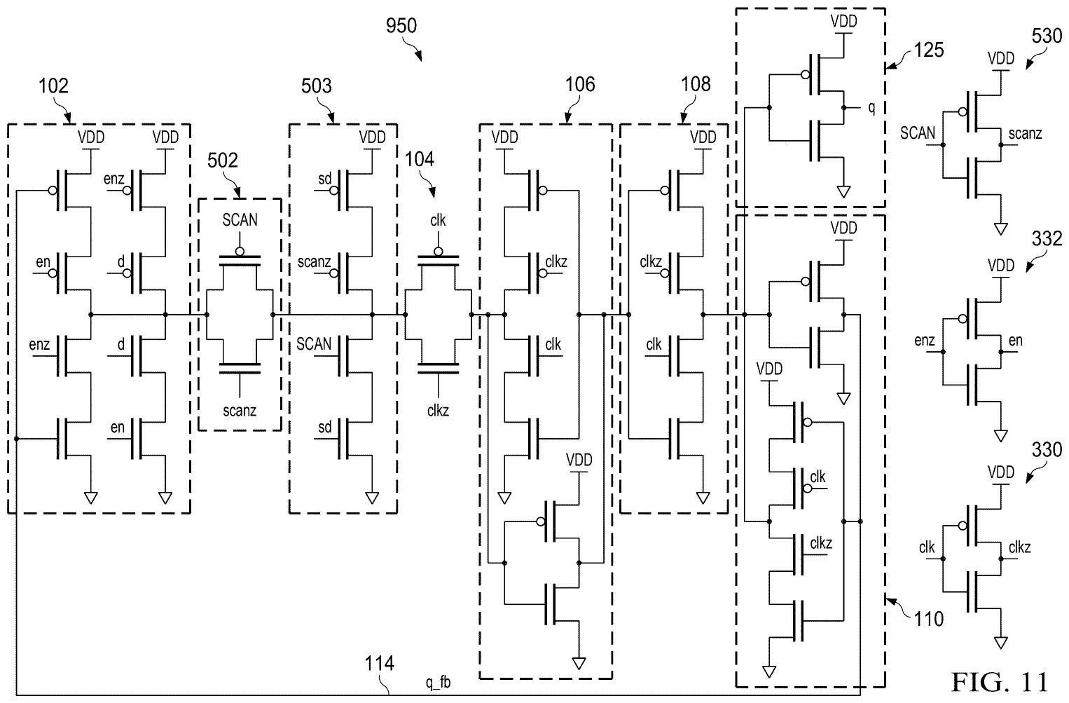

The result of the transformation in FIGS. 9-10 is a savings of at least four transistors total. FIG. 11 is a transistor-level illustration of an implementation of scan enable flip-flop 950 of FIGS. 9A-B, according to some embodiments.

In the example of scan enable flip-flop 950, the inverting multiplexer 102 is implemented using eight total transistors, which receive at their control terminals either the enable signal (enz), the complement (en) of the enable signal, or the data signal d. The output of the inverting multiplexer 102 is coupled with an input node of transmission gate 502. Transmission gate 502 is configured as shown above in FIG. 10. The output of transmission gate 502 is coupled with an input of master latch 106. The output of the slave latch 110 is fed back to the input of the inverting multiplexer 102 via a feedback line 114. An inverter 330 illustrates the relationship between the clock signal clk and the complement (clkz) of the clock signal. Of note in FIG. 11 is that the transmission gate 502 includes a PMOS transistor and an NMOS transistor coupled at their current path terminals (e.g., source/drain coupling) with the input of transmission gate 502 coupled to the output of inverting multiplexer 102 and the output coupled to tri-state inverter 503 and the input of transmission gate 104. Also of note in FIG. 11 is that tri-state inverter 503 is implemented using two PMOS transistors and two NMOS transistors, where the current path terminals of the scanz PMOS transistor and the scan NMOS transistor are coupled to a node that serves as the output of transmission gate 502 and the input of transmission gate 104.

The substitution of FIG. 10 is not limited to the flip-flop 950 of FIGS. 9A-B and FIG. 11. Rather, the scope of implementations may include any type of circuit having an inverter coupled in series with a tri-state inverter. Some engineers may work from a library of circuits, where individual circuits may be picked from the library and implemented in a larger circuit design. One technique may include searching through the individual circuits from the library and making the transformation of FIG. 10 for a particular individual circuit in the event of finding an inverter coupled in series with a tri-state inverter.

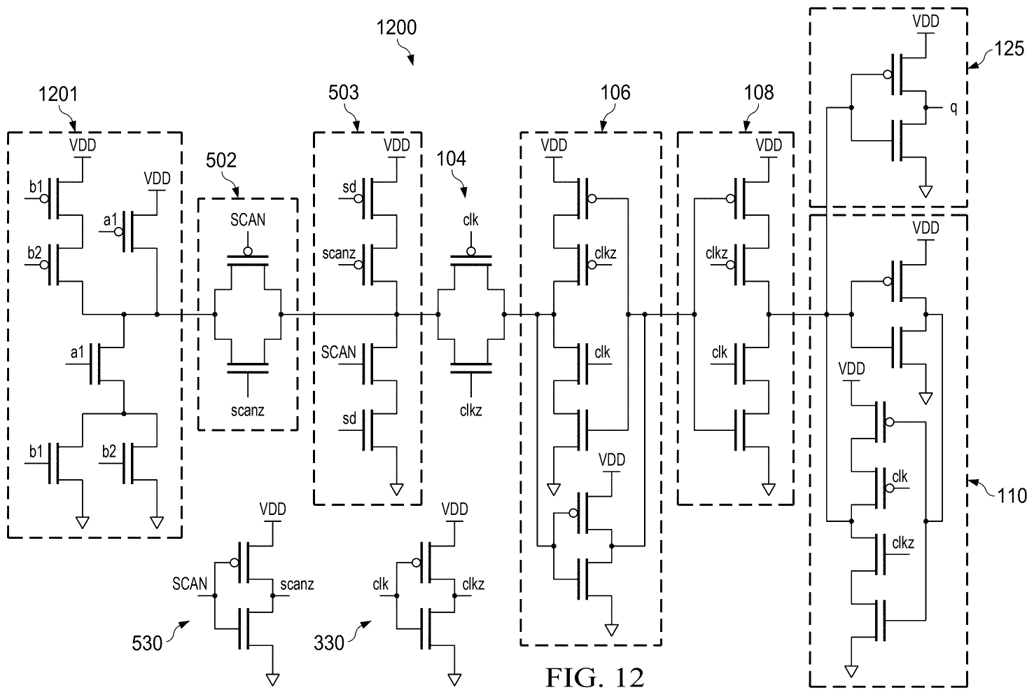

For instance, FIG. 12 is an illustration of an example flip-flop 1200, which is different from the flip-flop of FIGS. 9A-B, yet includes a transmission gate used in a similar manner as transmission gate 502 in FIG. 11.

Flip-flop 1200 includes Boolean logic 1201, which receives inputs a1, b1, and b2. The Boolean logic 1201 applies a function to those inputs and generates an output at an output node. The output node of the Boolean logic 1201 is at an input node of the transmission gate 502. The transmission gate 502 is disposed in series between the Boolean logic 1201 and the transmission gate 104 and, thus, is in series with the input to the master latch 106. When the scan enable signal is a digital 0, transmission gate 502 is ON, and tri-state inverter 503 is OFF. As a result, the output of the Boolean logic 1201 is applied to the input of master latch 106. When the scan enable signal is a digital 1, transmission gate 502 is OFF, thereby isolating the Boolean logic 1201 from the input of the master latch 106. When the transmission gate 502 is OFF, the tri-state inverter 503 is ON, thereby applying an inverted version of the scan data signal to the input of the master latch 106.

It is possible to create a similar flip-flop to flip-flop 1200, but implementing an inverter in series with a tri-state inverter instead of implementing transmission gate 502. However, the embodiment illustrated in FIG. 12 may provide a savings of at least four transistors by using transmission gate 502, as explained above with respect to FIG. 10.

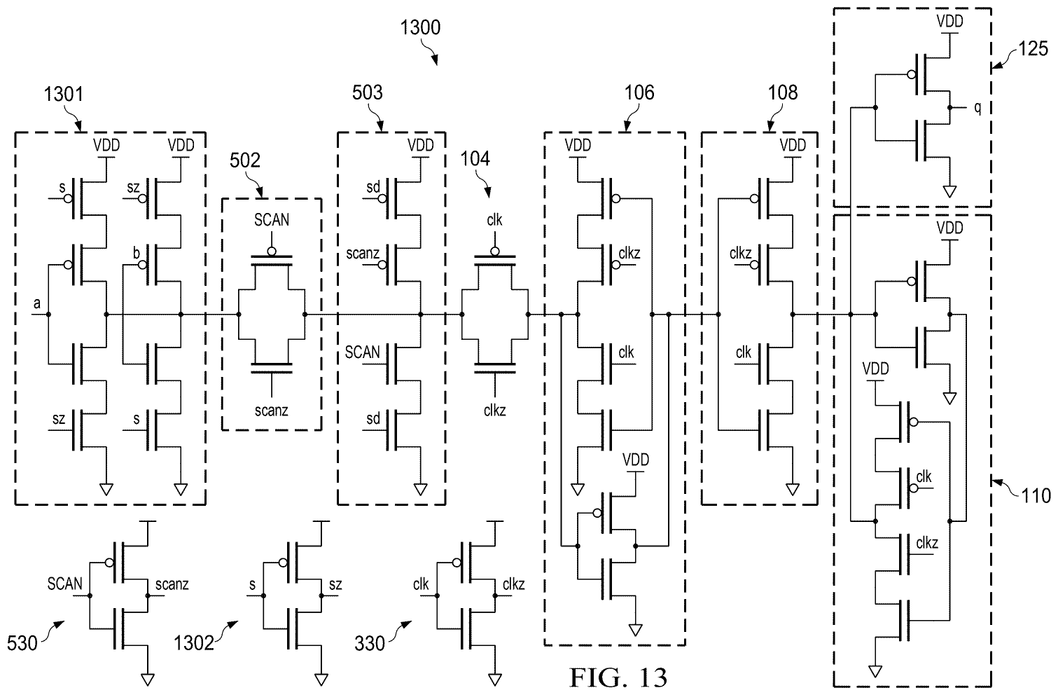

FIG. 13 is an illustration of an example flip-flop 1300, which is different from the flip-flop 1200 of FIG. 12, and it includes the same transistor savings as described above with respect to FIG. 12. Specifically, flip-flop 1300 provides multiplexing among the inputs a and b using multiplexer select signal s. Flip-flop 1300 may further include inverter 1302 to generate sz. The output node of the multiplexer 1301 is at an input node of the transmission gate 502. The embodiment illustrated in FIG. 13 may provide a savings of four transistors by using transmission gate 502, as explained above with respect to FIG. 10.

Example embodiments of the present disclosure are summarized here. Other embodiments can also be understood from the entirety of the specification and the claims filed herein.

Example 1. A circuit including: a first inverter having an output; a first transmission gate having an input, an output, and an enable input, where the input of the first transmission gate is coupled to the output of the first inverter; a first latch having an input and an output, the input of the first latch coupled to the output of the first transmission gate; a second latch having an input and an output, the input of the second latch coupled to the output of the first latch; and a second transmission gate having an input and an output, the input of the second transmission gate coupled to the output of the second latch.

Example 2. The circuit of example 1, where the enable input of the first transmission gate is configured to receive a first enable signal, and where an enable input of the second transmission gate is configured to receive the first enable signal.

Example 3. The circuit of one of examples 1 or 2, further including: a third transmission gate having an input and an output, where the input of the third transmission gate is coupled to the output of the second latch, and where the output of the third transmission gate is coupled to the input of the second latch.

Example 4. The circuit of one of examples 1 to 3, where the second latch includes a second inverter and a third inverter cross-coupled with the second inverter.

Example 5. The circuit of one of examples 1 to 4, where the input of the third transmission gate is coupled to an output of the third inverter.

Example 6. The circuit of one of examples 1 to 5, further including: a fourth transmission gate having an input and an output, where the input of the fourth transmission gate is coupled to the output of the first transmission gate, and where the output of the fourth transmission gate is coupled to the input of the first latch.

Example 7. The circuit of one of examples 1 to 6, where the third transmission gate includes an enable input configured to receive a first clock signal, and where the fourth transmission gate includes an enable input configured to receive the first clock signal.

Example 8. The circuit of one of examples 1 to 7, where the first latch includes: a first tri-state inverter having an input and an output, the input of the first tri-state inverter coupled to the output of the first latch, and the output of the first tri-state inverter is coupled to the input of the first latch; and a second inverter having an input and an output, the input of the second inverter coupled to the input of the first latch, and the output of the second inverter coupled to the output of the first latch.

Example 9. The circuit of one of examples 1 to 8, further including: a second tri-state inverter having an input, an output, and an enable input, the input of the second tri-state inverter coupled to the output of the second inverter, the output of the second tri-state inverter coupled to the input of the second latch, and the enable input of the second tri-state inverter configured to receive a clock signal, where an enable input of the first tri-state inverter is configured to receive the clock signal.

Example 10. The circuit of one of examples 1 to 9, where the first latch has a first tri-state inverter having an input and an output, the input of the first tri-state inverter coupled to the output of the first latch, and the output of the first tri-state inverter is coupled to the input of the first latch, where the first latch includes a first NOR gate cross-coupled with the first tri-state inverter so that a first input of the first NOR gate is coupled to the output of the first tri-state inverter and the output of the first NOR gate is coupled to the input of the first tri-state inverter, the first NOR gate having a second input configured to receive a clear signal, where the circuit further includes a second NOR gate having a first input and a second input configured to receive a clock signal and the clear signal, respectively, where the second NOR gate further includes an output coupled to a second inverter, where an output of the second inverter is coupled to the first tri-state inverter, and where the output of the second NOR gate is coupled to the first tri-state inverter.

Example 11. The circuit of one of examples 1 to 10, further including an output terminal coupled to the output of the second latch.

Example 12. The circuit of one of examples 1 to 11, further including: an output terminal; and a second inverter having an input coupled to the output of the first latch, and an output coupled to the output terminal.

Example 13. The circuit of one of examples 1 to 12, further including: a first tri-state inverter having an output coupled to a first intermediate node that is coupled between the output of the first inverter and the input of the first latch; and a third transmission gate having an input and an output, the input of the third transmission gate coupled to the output of the first inverter, and the output of the third transmission gate coupled to the first intermediate node and where the first inverter is a tri-state inverter having an enable input configured to receive a first enable signal and includes the first transmission gate.

Example 14. The circuit of one of examples 1 to 13, where an input of the first inverter is configured to receive a first data signal, where an input of the first tri-state inverter is configured to receive a second data signal, where an enable input of the first tri-state inverter is configured to receive a scan enable signal, and where an enable input of the third transmission gate is configured to receive the scan enable signal.

Example 15. The circuit of one of examples 1 to 14, further including a fourth transmission gate coupled in series with the second transmission gate, the fourth transmission gate having an enable input configured to receive the scan enable signal, where an enable input of the second transmission gate is configured to receive a first enable signal.

Example 16. The circuit of one of examples 1 to 15, where the first inverter, the first transmission gate, the first tri-state inverter, and the third transmission gate are configured as an arrangement of transistors, the arrangement of transistors including: a first plurality of transistors arranged in series, where the first plurality of transistors are configured to receive the first data signal, the first enable signal, and the scan enable signal at a first plurality of control terminals; a second plurality of transistors arranged in series, where the second plurality of transistors are configured to receive the first data signal, a complement of the first enable signal, and a complement of the scan enable signal and a second plurality of control terminals; a third plurality of transistors arranged in series, where the third plurality of transistors are coupled to the first plurality of transistors, the third plurality of transistors being configured to receive the second data signal and the complement of the second enable signal at a third plurality of control terminals; and a fourth plurality of transistors arranged in series, where the fourth plurality of transistors are coupled to the second plurality of transistors, the fourth plurality of transistors being configured to receive the second data signal and the scan enable signal at a fourth plurality of control terminals.

Example 17. The circuit of one of examples 1 to 16, where the first inverter, the first tri-state inverter, and the third transmission gate are configured as an arrangement of transistors, the arrangement of transistors including: a first plurality of transistors arranged in series, where the first plurality of transistors are configured to receive the first data signal and the scan enable signal at a first plurality of control terminals; a second plurality of transistors arranged in series, where the second plurality of transistors are configured to receive the first data signal and a complement of the scan enable signal at a second plurality of control terminals; a third plurality of transistors arranged in series and coupled to the first plurality of transistors, where the third plurality of transistors are configured to receive the second data signal and the complement of the scan enable signal at a third plurality of control terminals; and a fourth plurality of transistors arranged in series and coupled to the second plurality of transistors, where the fourth plurality of transistors are configured to receive the second data signal and the scan enable signal at a fourth plurality of control terminals.

Example 18. The circuit of one of examples 1 to 17, where the feedback path does not include a transmission gate configured to receive the scan enable signal, and where the first enable signal and the scan enable signal are gated by a NOR gate.

Example 19. A flip-flop circuit including: a first input configured to receive a first data signal; a first latch coupled in series with the first input; a second latch coupled in series with the first latch; and a first transmission gate, coupled on a feedback path between the first latch and the second latch, where the first transmission gate includes a first enable input configured to receive a first enable signal.

Example 20. The flip-flop circuit of example 19, further including: a first tri-state inverter, having the first input, where the first tri-state inverter is coupled in series with a second transmission gate, where the second transmission gate includes a second enable input configured to receive a second enable signal.

Example 21. The flip-flop circuit of one of examples 19 or 20, where the first tri-state inverter includes a third enable input configured to receive the first enable signal.

Example 22. The flip-flop circuit of one of examples 19 to 21, where the second enable signal includes a scan enable signal.

Example 23. The flip-flop circuit of one of examples 19 to 22, further including: a second tri-state inverter having a second input configured to receive a second data signal, where the second tri-state inverter is further configured to receive the second enable signal; and a third transmission gate, where the third transmission gate is disposed in the feedback path between the second latch and the first transmission gate, where the third transmission gate is configured to receive the second enable signal; where the second transmission gate is configured to receive an output of the first tri-state inverter, and where the second transmission gate is disposed between the first tri-state inverter and the first latch.

Example 24. The flip-flop circuit of one of examples 19 to 23, where the first tri-state inverter, the second tri-state inverter, and the second transmission gate are configured as an arrangement of transistors, the arrangement of transistors including: a first plurality of transistors arranged in series, where the first plurality of transistors are configured to receive the first data signal, the first enable signal, and the second enable signal at a first plurality of control terminals; a second plurality of transistors arranged in series, where the second plurality of transistors are configured to receive the first data signal, a complement of the first enable signal, and a complement of the second enable signal and a second plurality of control terminals; a third plurality of transistors arranged in series, where the third plurality of transistors are coupled to the first plurality of transistors, the third plurality of transistors being configured to receive the second data signal and the complement of the second enable signal at a third plurality of control terminals; and a fourth plurality of transistors arranged in series, where the fourth plurality of transistors are coupled to the second plurality of transistors, the fourth plurality of transistors being configured to receive the second data signal and the second enable signal at a fourth plurality of control terminals.

Example 25. The flip-flop circuit of one of examples 19 to 24, further including: a second tri-state inverter having a second input configured to receive a second data signal, where the second tri-state inverter is further configured to receive a second enable signal; where the second transmission gate is configured to receive an output of the first tri-state inverter, and where the second transmission gate is disposed between the first tri-state inverter and the first latch.

Example 26. The flip-flop circuit of one of examples 19 to 25, where the first tri-state inverter, the second tri-state inverter, and the second transmission gate are configured as an arrangement of transistors, the arrangement of transistors including: a first plurality of transistors arranged in series, where the first plurality of transistors are configured to receive the first data signal and the second enable signal at a first plurality of control terminals; a second plurality of transistors arranged in series, where the second plurality of transistors are configured to receive the first data signal and a complement of the second enable signal at a second plurality of control terminals; a third plurality of transistors arranged in series and coupled to the first plurality of transistors, where the third plurality of transistors are configured to receive the second data signal and the complement of the second enable signal at a third plurality of control terminals; and a fourth plurality of transistors arranged in series in coupled to the second plurality of transistors, where the fourth plurality of transistors are configured to receive the second data signal and the second enable signal at a fourth plurality of control terminals.

Example 27. A multiplexer circuit including: a first data input configured to receive a first data signal; a transmission gate coupled with the first data input, where the transmission gate includes a first data output, a first enable input configured to receive an enable signal, and a second enable input configured to receive a complementary enable signal; and a tri-state inverter including: a second data input configured to receive a second data signal, a third enable input configured to receive the enable signal, and a fourth enable input configured to receive the complementary enable signal; where a second data output of the tri-state inverter is coupled to the first data output.

Example 28. The multiplexer circuit of example 27, where the second data signal includes a scan data signal.

Example 29. The multiplexer circuit of one of examples 27 or 28, where the transmission gate includes: a first transistor and a second transistor coupled in parallel, where a first control terminal of the first transistor is configured as the first enable input, and where a second control terminal of the second transistor is configured as the second enable input.

Example 30. The multiplexer circuit of one of examples 27 to 29, where the tri-state inverter includes: a third transistor; a fourth transistor; a fifth transistor; and a sixth transistor, where the third transistor, the fourth transistor, the fifth transistor, and the sixth transistor are arranged in series, and where the fourth transistor and the fifth transistor are coupled at the first data output.

Example 31. The multiplexer circuit of one of examples 27 to 30, where: the third transistor is configured to receive the data signal at a third control terminal, the fourth transistor is configured to receive the complementary enable signal at a fourth control terminal; the fifth transistor is configured to receive the control signal at a fifth control terminal; and the sixth transistor is configured to receive the data signal at a sixth control terminal.

Example 32. The multiplexer circuit of one of examples 27 to 31, where the third transistor and the fourth transistor are of a first transistor type, and where the fifth transistor and the sixth transistor are of a complementary transistor type.

Example 33. The multiplexer circuit of one of examples 27 to 32, where the third transistor, the fourth transistor, the fifth transistor, and the sixth transistor are coupled in series between a power supply and a complementary power supply.

Example 34. A flip-flop including: a multiplexer having a first multiplexer input; a transmission gate having a first data input coupled with an output of the multiplexer, where the transmission gate includes a first data output, a first enable input configured to receive an enable signal, and a second enable input configured to receive a complementary enable signal; a tri-state inverter including: a second data input, a third enable input configured to receive the enable signal, and a fourth enable input configured to receive the complementary enable signal, where a second data output of the tri-state inverter is coupled to the first data output; a first latch having an input coupled to the second data output; and a second latch having an input coupled to an output of the first latch, where an output of the second latch is coupled to the first multiplexer input.

Example 35. The flip-flop of example 34, where the multiplexer includes a second multiplexer input that is configured to receive a first data signal, where the second data input is configured to receive a second data signal.

Various embodiments described herein may be used to reduce a quantity of transistors in a logic circuit, such as a flip-flop. For instance, some of the embodiments may save two transistors, four transistors, or even more, depending on the amount of transformations that can be made. An advantage of using a reduced quantity of transistors may include saving area in a semiconductor circuit, especially when such logic circuits may be implemented in relatively large numbers within the semiconductor circuit. A reduction in transistors may allow for a reduction in leakage current and in operating current as well.

Various embodiments may implement logic circuits, such as flip-flops, in various applications. One such application may include a frequency dividers circuit, which may include multiple flip-flops. Furthermore, flip-flops may be used as digital storage elements in digital processing circuits. In fact, logic circuits may be implemented in many different applications. Furthermore, such circuits may be implemented on semiconductor dies, and the semiconductor dies may further be implemented in semiconductor packages.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A circuit comprising:
a first inverter having an output;
a first transmission gate having an input, an output, and an enable input, wherein the input of the first transmission gate is coupled to the output of the first inverter;
a first latch having an input and an output, the input of the first latch coupled to the output of the first transmission gate;
a second latch having an input and an output, the input of the second latch coupled to the output of the first latch; and
a second transmission gate having an input and an output, the input of the second transmission gate coupled to the output of the second latch.

2. The circuit of claim 1, wherein the enable input of the first transmission gate is configured to receive a first enable signal, and wherein an enable input of the second transmission gate is configured to receive the first enable signal.

3. The circuit of claim 1, further comprising:
a third transmission gate having an input and an output, wherein the input of the third transmission gate is coupled to the output of the second latch, and wherein the output of the third transmission gate is coupled to the input of the second latch.

4. The circuit of claim 3, wherein the second latch comprises a second inverter and a third inverter cross-coupled with the second inverter.

5. The circuit of claim 4, wherein the input of the third transmission gate is coupled to an output of the third inverter.

6. The circuit of claim 3, further comprising:
a fourth transmission gate having an input and an output, wherein the input of the fourth transmission gate is coupled to the output of the first transmission gate, and wherein the output of the fourth transmission gate is coupled to the input of the first latch.

7. The circuit of claim 6, wherein the third transmission gate comprises an enable input configured to receive a first clock signal, and wherein the fourth transmission gate comprises an enable input configured to receive the first clock signal.

8. The circuit of claim 1, wherein the first latch comprises:
a first tri-state inverter having an input and an output, the input of the first tri-state inverter coupled to the output of the first latch, and the output of the first tri-state inverter is coupled to the input of the first latch; and
a second inverter having an input and an output, the input of the second inverter coupled to the input of the first latch, and the output of the second inverter coupled to the output of the first latch.

9. The circuit of claim 8, further comprising:
a second tri-state inverter having an input, an output, and an enable input, the input of the second tri-state inverter coupled to the output of the second inverter, the output of the second tri-state inverter coupled to the input of the second latch, and the enable input of the second tri-state inverter configured to receive a clock signal, wherein an enable input of the first tri-state inverter is configured to receive the clock signal.

10. The circuit of claim 1, wherein the first latch has a first tri-state inverter having an input and an output, the input of the first tri-state inverter coupled to the output of the first latch, and the output of the first tri-state inverter is coupled to the input of the first latch, wherein the first latch comprises a first NOR gate cross-coupled with the first tri-state inverter so that a first input of the first NOR gate is coupled to the output of the first tri-state inverter and the output of the first NOR gate is coupled to the input of the first tri-state inverter, the first NOR gate having a second input configured to receive a clear signal,
wherein the circuit further includes a second NOR gate having a first input and a second input configured to receive a clock signal and the clear signal, respectively, wherein the second NOR gate further includes an output coupled to a second inverter, wherein an output of the second inverter is coupled to the first tri-state inverter, and wherein the output of the second NOR gate is coupled to the first tri-state inverter.

11. The circuit of claim 1, further comprising an output terminal coupled to the output of the second latch.

12. The circuit of claim 1, further comprising:
an output terminal; and
a second inverter having an input coupled to the output of the first latch, and an output coupled to the output terminal.

13. The circuit of claim 1, further comprising:
a first tri-state inverter having an output coupled to a first intermediate node that is coupled between the output of the first inverter and the input of the first latch; and
a third transmission gate having an input and an output, the input of the third transmission gate coupled to the output of the first inverter, and the output of the third transmission gate coupled to the first intermediate node and wherein the first inverter is a tri-state inverter having an enable input configured to receive a first enable signal and comprises the first transmission gate.

14. The circuit of claim 13, wherein an input of the first inverter is configured to receive a first data signal, wherein an input of the first tri-state inverter is configured to receive a second data signal, wherein an enable input of the first tri-state inverter is configured to receive a scan enable signal, and wherein an enable input of the third transmission gate is configured to receive the scan enable signal.

15. The circuit of claim 14, further comprising a fourth transmission gate coupled in series with the second transmission gate, the fourth transmission gate having an enable input configured to receive the scan enable signal, wherein an enable input of the second transmission gate is configured to receive a first enable signal.

16. The circuit of claim 14, wherein the first inverter, the first transmission gate, the first tri-state inverter, and the third transmission gate are configured as an arrangement of transistors, the arrangement of transistors comprising:
a first plurality of transistors arranged in series, wherein the first plurality of transistors are configured to receive the first data signal, the first enable signal, and the scan enable signal at a first plurality of control terminals;
a second plurality of transistors arranged in series, wherein the second plurality of transistors are configured to receive the first data signal, a complement of the first enable signal, and a complement of the scan enable signal and a second plurality of control terminals;
a third plurality of transistors arranged in series, wherein the third plurality of transistors are coupled to the first plurality of transistors, the third plurality of transistors being configured to receive the second data signal and the complement of the second enable signal at a third plurality of control terminals; and
a fourth plurality of transistors arranged in series, wherein the fourth plurality of transistors are coupled to the second plurality of transistors, the fourth plurality of transistors being configured to receive the second data signal and the scan enable signal at a fourth plurality of control terminals.

17. The circuit of claim 14, wherein the first inverter, the first tri-state inverter, and the third transmission gate are configured as an arrangement of transistors, the arrangement of transistors comprising:
a first plurality of transistors arranged in series, wherein the first plurality of transistors are configured to receive the first data signal and the scan enable signal at a first plurality of control terminals;
a second plurality of transistors arranged in series, wherein the second plurality of transistors are configured to receive the first data signal and a complement of the scan enable signal at a second plurality of control terminals;
a third plurality of transistors arranged in series and coupled to the first plurality of transistors, wherein the third plurality of transistors are configured to receive the second data signal and the complement of the scan enable signal at a third plurality of control terminals; and
a fourth plurality of transistors arranged in series and coupled to the second plurality of transistors, wherein the fourth plurality of transistors are configured to receive the second data signal and the scan enable signal at a fourth plurality of control terminals.

18. The circuit of claim 17, wherein the feedback path does not include a transmission gate configured to receive the scan enable signal, and wherein the first enable signal and the scan enable signal are gated by a NOR gate.

19. A flip-flop comprising:
a multiplexer having a first multiplexer input;
a transmission gate having a first data input coupled with an output of the multiplexer, wherein the transmission gate comprises a first data output, a first enable input configured to receive an enable signal, and a second enable input configured to receive a complementary enable signal;
a tri-state inverter comprising: a second data input, a third enable input configured to receive the enable signal, and a fourth enable input configured to receive the complementary enable signal, wherein a second data output of the tri-state inverter is coupled to the first data output;
a first latch having an input coupled to the second data output; and
a second latch having an input coupled to an output of the first latch, wherein an output of the second latch is coupled to the first multiplexer input.

20. The flip-flop of claim 19, wherein the multiplexer includes a second multiplexer input that is configured to receive a first data signal, wherein the second data input is configured to receive a second data signal.
